(19) United States
(12) Patent Application Publication
(10) Pub. No.: US 2008/0029825 A1
(43) Pub. Date: Feb. 7, 2008

(54) Semiconductor device and method of manufacturing the same

(76) Inventors: Kentaro Saito, Tokyo (JP); Yasushi Ishii, Tokyo (JP); Munekatsu Nakagawa, Tokyo (JP); Satoru Machida, Tokyo (JP); Masaru Nakamichi, Tokyo (JP)

Correspondence Address: MCDERMOTT WILL & EMERY LLP, 600 13TH STREET, N.W., WASHINGTON, DC, 20005-3096, US

(21) Appl. No.: 11/882,594

(22) Filed: Aug. 2, 2007

(30) Foreign Application Priority Data
Aug. 4, 2006 (JP) 2006-213535(P)

(51) Int. Cl. H01L 29/76; H01L 21/3205

(52) U.S. Cl. 257/371; 438/591; 257/E21.211

(57) ABSTRACT

Even if it is the semiconductor device provided with the wiring on an isolation insulating film, the sidewall formed on the side surface of this wiring, and the shared contact which connects the wiring and the impurity diffusion on an active region, the semiconductor device which can suppress the generation of the leakage current from shared contact to a semiconductor substrate, and its manufacturing method are offered. The semiconductor device concerning the present invention is provided with an isolation insulating film selectively formed on the main front surface of a semiconductor substrate, an active region specified by an isolation insulating film on the main front surface of a semiconductor substrate, a recess which reaches an active region on the isolation insulating film, the first insulating film formed so that a recess might be covered, the second insulating film which is formed on a first insulating film, is filled up with a recess, and differs in a material from the first insulating film, an impurity diffused layer formed on the main front surface of the active region of the position which adjoins the recess, and an electric conduction film formed on the impurity diffused layer.

### CROSS-REFERENCE TO RELATED APPLICATION

The present application claims priority from Japanese patent application No. 2006-213535 filed on Aug. 4, 2006, the content of which is hereby incorporated by reference into this application.

### 1. FIELD OF THE INVENTION

The present invention relates to a semiconductor device and its manufacturing method.

### 2. DESCRIPTION OF THE BACKGROUND ART

As one of the semiconductor devices, the full CMOS static type semiconductor memory device (“SRAM (Static Random Access Memory)” is called hereafter) is known from the former.

This SRAM has a plurality of memory cells on the main front surface of a semiconductor substrate, and each memory cell is provided with six MOS transistors.

This SRAM is provided with the isolation region, the active region formed on N well region formed on the main front surface of a semiconductor substrate, and the active region formed on P well region located in the both sides of this N well region. This SRAM is provided with two PMOS transistors formed on the active region in N well region, and the NMOS transistor formed two in each on the active region in a P well each region, respectively.

And one NMOS transistor is an access transistor between two NMOS transistors formed on the P well each region, and the NMOS transistor of the other functions as a drive transistor. Two PMOS transistors formed on N well region function as a load transistor.

And the gate electrode of a drive transistor and the gate electrode of the load transistor are formed with the electric conduction film extending and existing ranging from N well region to P well region.

When manufacturing such a semiconductor device, it is necessary to suppress the generation of leak by being able to dig an isolation region, and falling or a contact hole doing a position drift.

And in Japanese Unexamined Patent Publication No. 2003-37115 and Japanese Unexamined Patent Publication No. 2000-174125, when forming the contact connected to the impurity diffused layer on an active region, the semiconductor device with which the short-circuit and leak by an alignment drift of the contact hole were suppressed, and its manufacturing method are offered.

The manufacturing method of the semiconductor device described to Japanese Unexamined Patent Publication No. 2003-37115 is a manufacturing method of the semiconductor device which has an element isolation region of trench isolation structure in a semiconductor substrate, and forms a gate electrode in an element formation region first. And the first insulating film which consists of a silicon oxide film is deposited on a semiconductor substrate, and the second insulating film which consists of a silicon nitride film is deposited further. Then, a second insulating film is etched back by using a first insulating film as a stopper, and the first sidewall which consists of a second insulating film is formed via a first insulating film on the side surface of a gate electrode.

And a first insulating film is etched and the second sidewall which consists of a first insulating film is formed on the side surface of a gate electrode. Here, since a first insulating film and a second insulating film are thin, they can suppress the embedded oxide film decrease in a trench from the case where etching a thick oxide film at once and a sidewall is formed. Hereby, leak between the contact and the semiconductor substrate which did the position drift can be suppressed.

In the manufacturing method of the semiconductor device described to Japanese Unexamined Patent Publication No. 2000-174125, first, an element isolation insulating film is embedded at the main front surface of a semiconductor substrate, and n type diffusion layer is formed in it. And an interlayer insulation film is formed and a contact hole is formed in this interlayer insulation film so that this n type diffusion layer may be covered. When a contact hole partly overlaps an element isolation insulating film with an alignment drift, a side wall insulating film is formed in a contact hole so that the trench formed in an element isolation insulating film may be filled. Then, an electric conduction film is formed in a contact hole.

According to the manufacturing method of the semiconductor device described to Japanese Unexamined Patent Publication No. 2004-273642, a wiring is formed in the located portion at the side of the source region among the upper surfaces of the insulating film for separation, and a sidewall is formed on the side surface of this wiring. And the shared contact which connects this wiring and source region is formed. Here, the sidewall formed on the side surface at the side of the source region of a wiring is high by the level difference of the insulating film for separation, and is formed.

For this reason, when forming the contact hole of the shared contact which connects between the source region and wirings, it is suppressed that the sidewall formed on the side surface at the side of the source region is removed thoroughly. It is suppressed by this that the front surface of the semiconductor substrate located under a sidewall is exposed, and it can suppress that leakage current occurs between shared contact and a semiconductor substrate.

[Patent Reference 1] Japanese Unexamined Patent Publication No. 2003-37115

[Patent Reference 2] Japanese Unexamined Patent Publication No. 2000-174125

[Patent Reference 3] Japanese Unexamined Patent Publication No. 2004-273642

### SUMMARY OF THE INVENTION

However, in the manufacturing method of the semiconductor device described to the above-mentioned Japanese Unexamined Patent Publication No. 2003-37115, film decrease also of the buried insulating film is greatly done depending on the thickness of a first insulating film and a second insulating film. That is, the thickness of the first and a second insulating film has a possibility that leakage current may occur to a semiconductor substrate.

In the manufacturing method of the semiconductor device described to the above-mentioned Japanese Unexamined Patent Publication No. 2000-1741245, when forming a contact hole, the recess is already formed in the element isolation insulating film and a contact hole is formed, there is a possibility that an element isolation insulating film may penetrate.

The timing by which a groove is formed in an element isolation insulating film may be generated, also when it is not restricted to a position drift of a contact hole, for example, the sidewall of the wiring formed on the element isolation insulating film is formed.

In the manufacturing method of the semiconductor device described to Japanese Unexamined Patent Publication No. 2004-273642, it aims at suppressing film decrease of the sidewall formed on the side surface of a wiring, and has not aimed at suppressing film decrease of an isolation insulating film.

The present invention is made in view of the above problems. A purpose of the present invention is to offer the semiconductor device which can suppress that leakage current occurs in a semiconductor substrate, and its manufacturing method, even if film decrease occurs in an isolation insulating film, while suppressing the film decrease generated in an isolation insulating film.

A semiconductor device concerning the present invention, in one aspect, comprises a semiconductor substrate which has a main front surface, an isolation insulating film selectively formed over a main front surface of the semiconductor substrate, an active region specified by the isolation insulating film over a main front surface of the semiconductor substrate, a recess which reaches the active region over the isolation insulating film, a first insulating film formed in the recess, a second insulating film which is formed over the first insulating film, fills up the recess, and differs in material from the first insulating film, an impurity diffused layer formed in a front surface of the active region of a position which adjoins the recess, and a conductive layer which is formed over the impurity diffused layer and is electrically connected with the impurity diffused layer.

A semiconductor device concerning the present invention, in other aspect, comprises a semiconductor substrate which has a main front surface, an isolation insulating film selectively formed over a main front surface of the semiconductor substrate, an active region specified by the isolation insulating film over a main front surface of the semiconductor substrate, a first impurity diffused layer which was formed in a front surface of the active region which adjoins the isolation insulating film, and whose front surface was silicided, a second impurity diffused layer which is formed in a front surface of the active region making a gap with the first impurity diffused layer, and whose front surface is not silicided, a recess which reaches the first impurity diffused layer over the isolation insulating film, a first insulating film formed in the recess, and a second insulating film which is formed over the first insulating film, fills up the recess, and differs in material from the first insulating film, wherein at least, either the first insulating film or the second insulating film reaches the first impurity region.

A method of manufacturing a semiconductor device concerning the present invention, in one aspect, comprises the steps of forming an isolation insulating film which specifies an active region over a main front surface of a semiconductor substrate, introducing an impurity into a front surface of the active region which adjoins the isolation region, and forming an impurity diffused layer, forming a first insulating film so that the impurity diffused layer and the isolation insulating film may be covered, selectively etching the first insulating film, and exposing a front surface of the isolation insulating film at a side of the impurity diffused layer, forming a second insulating film in a recess formed by etching of the first insulating film so that it might reach the active region in the isolation insulating film front surface, filling up the recess with a third insulating film while forming the third insulating film whose material differs from the second insulating film over the second insulating film, and forming an electric conduction film electrically connected with this impurity diffused layer over the impurity diffused layer.

A method of manufacturing a semiconductor device concerning the present invention, in other aspect, comprises the steps of forming an isolation insulating film which specifies an active region over a main front surface of a semiconductor substrate, introducing an impurity into a front surface of the active region selectively, and forming a first impurity diffused layer in a front surface of the active region of a position which adjoins the isolation insulating film, introducing an impurity into a front surface of the active region selectively, and forming a second impurity region in a front surface of the active region making a gap with the first impurity region, forming a first insulating film so that the second impurity region and the isolation insulating film may be covered, etching the first insulating film selectively, and exposing a front surface of the isolation insulating film at a side of the first impurity diffused layer, forming a second insulating film in a recess formed so that it might reach the active region in a front surface of the isolation insulating film by etching of the first insulating film, filling up an inside of the recess with a third insulating film while forming the third insulating film whose material differs from the second insulating film over the second insulating film, forming a mask layer which covers the third insulating film, and exposes the first impurity diffused layer, and siliciding an exposed front surface of the first impurity diffused layer.

While suppressing the film decrease generated in an isolation insulating film according to the semiconductor device concerning the present invention, and its manufacturing method, even if film decrease occurs in an isolation insulating film, it can suppress that leakage current occurs in a semiconductor substrate.

### BRIEF DESCRIPTION OF THE DRAWINGS

FIG. 1 is a plan view of the memory cell of the semiconductor device (static semiconductor memory device) in an embodiment of the invention;

FIG. 2 is an equivalent circuit picture of the memory cell shown in FIG. 1;

FIG. 3 is a cross-sectional view in the III-III line of FIG. 1;

FIG. 4 is a cross-sectional view showing the fifth step of the manufacturing process of the semiconductor device concerning this embodiment;

FIG. 5 is a cross-sectional view showing the sixth step of the manufacturing process of the semiconductor device concerning this embodiment;

FIG. 6 is a cross-sectional view showing the seventh step of the manufacturing process of the semiconductor device concerning this embodiment;

FIG. 7 is a cross-sectional view showing the eighth step of the manufacturing process of the semiconductor device concerning this embodiment;

FIG. 8 is a cross-sectional view showing the ninth step of the manufacturing process of the semiconductor device concerning this embodiment;

FIG. 9 is a cross-sectional view showing the 10th step of the manufacturing process of the semiconductor device concerning this embodiment;

FIG. 10 is a cross-sectional view showing the 11th step of the manufacturing process of the semiconductor device concerning this embodiment;

FIG. 11 is a cross-sectional view showing the 12th step of the manufacturing process of the semiconductor device concerning this embodiment;

FIG. 12 is a cross-sectional view of the semiconductor device concerning this embodiment;

FIG. 13 is a cross-sectional view showing the first step of the manufacturing process of a semiconductor device;

FIG. 14 is a cross-sectional view showing the second step of the manufacturing process of a semiconductor device;

FIG. 15 is a cross-sectional view showing the third step of the manufacturing process of a semiconductor device;

FIG. 16 is a cross-sectional view showing the fourth step of the manufacturing process of a semiconductor device;

FIG. 17 is a cross-sectional view showing the sixth step of the manufacturing process of a semiconductor device;

FIG. 18 is a cross-sectional view showing the seventh step of the manufacturing process of a semiconductor device;

FIG. 19 is a cross-sectional view showing the eighth step of the manufacturing process of a semiconductor device;

FIG. 20 is a cross-sectional view showing the ninth step of the manufacturing process of a semiconductor device; and

FIG. 21 is a cross-sectional view showing the 12th step of the manufacturing process of a semiconductor device.

### DETAILED DESCRIPTION OF THE PREFERRED EMBODIMENTS

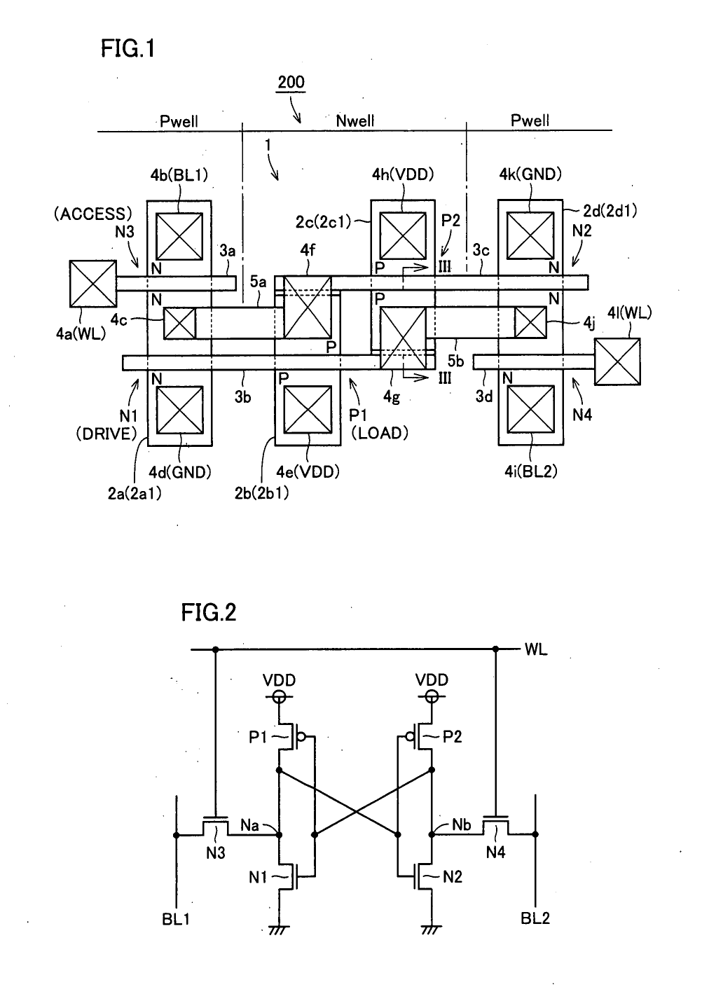

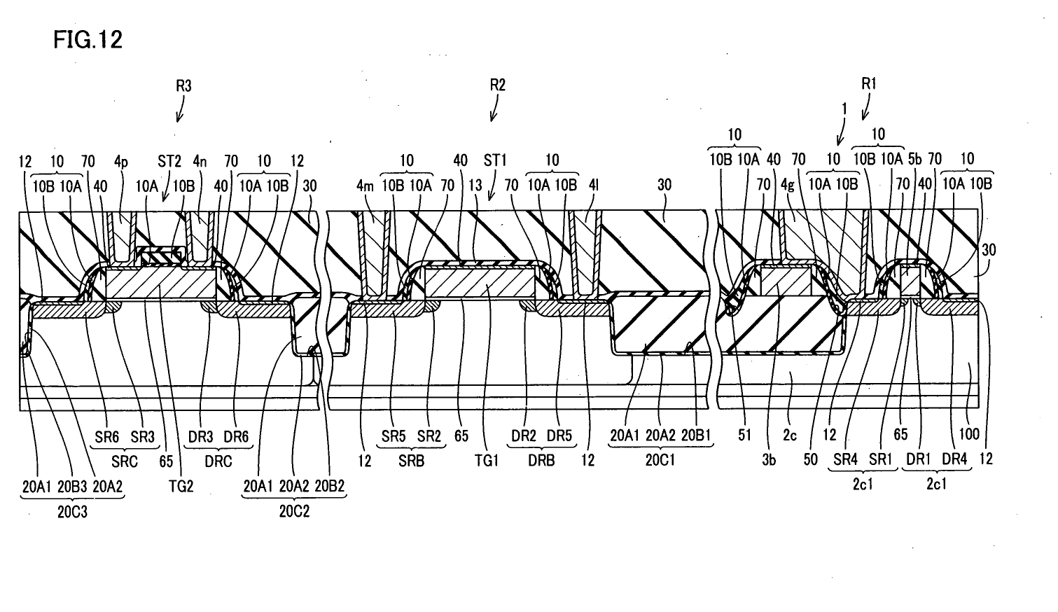

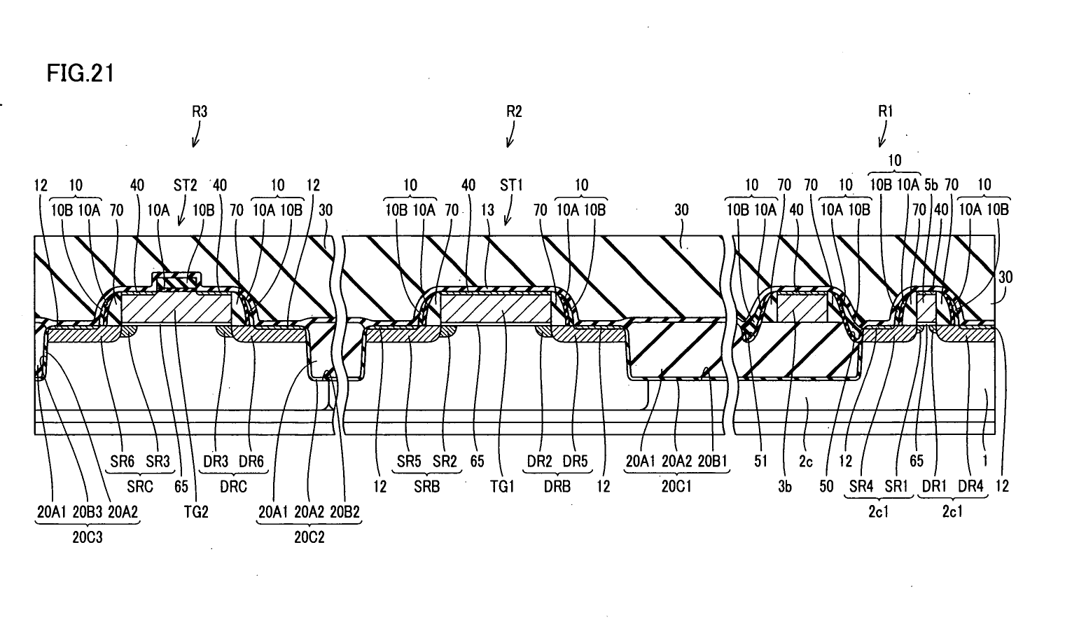

Hereafter, an embodiment of the invention is explained using FIG. 21 from FIG. 1. FIG. 1 is the plan view of memory cell 1 of full CMOSSRAM (static semiconductor memory device) formed in semiconductor device 200 in an embodiment of the invention. The equivalent circuit picture of this memory cell 1 is shown in FIG. 2. And FIG. 12 is a cross-sectional view of semiconductor device 200 concerning this embodiment. First, as shown in FIG. 12, semiconductor device 200 is provided with memory cell region R1 in which memory cell 1 of full CMOSSRAM was formed, first peripheral circuit area R2 in which first peripheral circuit transistor ST1 which performs motion control of memory cell 1 was formed, and second peripheral circuit area R3 in which second peripheral circuit transistor ST2 which performs motion control of memory cell 1 was formed.

Memory cell region R1, and the first, second peripheral circuit area R2 and R3 are specified by isolation region 20c1, 20c2, and 20c3 which were formed on the main front surface of semiconductor substrate 100.

On the main front surface of semiconductor substrate 100 in which memory cell region R1 is located, isolation region 20c1 and active region 2c specified by this isolation region 20c1 are formed. And on the main front surface of semiconductor substrate 100 in which active region 2c is located, gate insulating film 65, polysilicon wiring 5b formed on the upper surface of this gate insulating film 65, and impurity diffused layer 2c1 located in the both sides of this polysilicon wiring 5b are formed.

And first peripheral circuit transistor ST1 is provided with gate wiring TG1 formed via gate insulating film 65 on the main front surface of semiconductor substrate 100, and impurity diffused layers SRB and DRB formed on the main front surface of semiconductor substrate 100 located in the both sides of gate wiring TG1.

Impurity diffused layers SRB and DRB are contacted, respectively, and contact parts 4l and 4m which can apply voltage to each impurity diffused layers SRB and DRB are formed in impurity diffused layers SRB and DRB.

Second peripheral circuit transistor ST2 is formed like the above-mentioned first peripheral circuit transistor ST1. And, second peripheral circuit transistor ST2 is provided with gate wiring TG2 formed via gate insulating film 65 on the main front surface of semiconductor substrate 100, and impurity diffused layer SRC,DRC formed on the main front surface of semiconductor substrate 100 located in the both sides of this gate wiring TG2. Contact parts 4n and 4p are connected to gate wiring TG2.

Here, each impurity diffused layer 2c1, SRB, DRB, SRC, and DRC separate a gap mutually, and are formed. In this embodiment, although silicide film 12 is formed on the upper surface of impurity diffused layer 2c1, SRB, DRB, SRC, and DRC, it is not restricted to this. For example, it is good also as forming a non-silicide region, without forming silicide film 12 in the upper surface of impurity diffused layers SRC and DRC.

The structure of memory cell 1 of SRAM is briefly explained using FIG. 2. Memory cell 1 has full CMOS cell structure, and has the first, a second inverter, and two access NMOS transistors N3 and N4.

A first inverter includes first driver NMOS transistor N1 and first load PMOS transistor P1. A second inverter includes second driver NMOS transistor N2 and second load PMOS transistor P2.

A first inverter and a second inverter form the flip-flop which connected a mutual input and a mutual output. The source of first access NMOS transistor N3 is connected to first memory node Na of a flip-flop, and the source of second access NMOS transistor N4 is connected to second memory node Nb of a flip-flop.

Memory node Na is connected to bit line BL1 via first access NMOS transistor N3, and memory node Nb is connected to bit line BL2 via second access NMOS transistor N4. The gate of further the first, second access NMOS transistor N3, and N4 is connected to word line WL, and the source of the first, second load PMOS transistor P1, and P2 is connected to power supply line VDD.

Next, the layout of memory cell 1 of the above-mentioned full CMOSSRAM is explained. As shown in FIG. 1, P well region is formed in the both sides of N well region. N type impurities, such as phosphorus, are selectively implanted into active regions 2a and 2d formed in P well region, and impurity diffusion region 2a1 and 2d1 are formed in them. P type impurities, such as a boron, are selectively implanted into active regions 2b, 2c formed in N well region, and impurity diffusion region 2b1 and 2c1 are formed. On these specifications, active region 2a, 2b, and 2c and 2d are the regions comprising the region used as the source/drain of a transistor, and the region (board part) located between these regions of a reverse conductivity type to this region.

Both active regions 2a and 2d, active region 2b, and 2c have straight line-like form, and extend and exist it in the same direction (extending direction of P well region and N well region). Thereby, the width, and the variation of a formation position of P well region or N well region can be made small.

Memory cell 1 in this embodiment comprises six MOS transistors. Concretely, memory cell 1 comprises the first, the second driver NMOS transistor N1, N2, and the first, the second access NMOS transistor N3, N4 and the first, the second load PMOS transistor P1, P2.

The first, second access NMOS transistor N3, N4, and the first, second driver NMOS transistor N1 and N2 are formed on P well region of the both sides of N well region, respectively. The first, second load PMOS transistor P1, and P2 are formed on central N well region.

First access NMOS transistor N3 is formed in the intersection part of impurity diffusion region 2a1 comprising the region used as a source/drain, and polysilicon wiring 3a. Second access NMOS transistor N4 is formed in the intersection part of impurity diffusion region 2d1 comprising the region used as a source/drain, and polysilicon wirings 3d.

First driver NMOS transistor N1 is formed in the intersection part of impurity diffusion region 2a1 comprising the region used as a source/drain, and polysilicon wiring 3b. Second driver NMOS transistor N2 is formed in the intersection part of impurity diffusion region 2d1 comprising the region used as a source/drain, and polysilicon wiring 3c.

First load PMOS transistor P1 is formed in the intersection part of impurity diffusion region 2b1 comprising the region used as a source/drain, and polysilicon wiring 3b. Second access PMOS transistor P2 is formed in the intersection part of impurity diffusion region 2c1 comprising the region used as a source/drain, and polysilicon wiring 3c.

Polysilicon wirings 3a-3d constitute a gate of each MOS transistor, and as shown in FIG. 1, they are extending and existing in the same direction. Namely, polysilicon wirings 3a-3d are extending and existing in the direction in which it is a direction (horizontal direction in FIG. 1) vertical to the direction (longitudinal direction in FIG. 1) which P well region and N well region extend and exist, and P well region and N well region are located in a line.

The interlayer insulation film which is not illustrated is formed so that impurity diffusion region 2a1, 2d1, impurity diffusion region 2b1 and 2c1, and polysilicon wirings 3a-3d may be covered. Contact parts 4a-4l which reach impurity diffusion regions 2a and 2d, impurity diffusion region 2b and 2c, and polysilicon wirings 3a and 3d are formed. In these contact part 4a-4l, the conductive layer for connection with the upper wiring is embedded.

Contact parts 4a and 4l are gate contacts which reach a gate, and contact parts 4f and 4g are common contacts (Shared Contact) which reach an impurity diffusion region and a polysilicon wiring. The other contact parts 4b, 4c, 4d, 4e, 4h, 4i, 4j, and 4k are diffusion contacts which reach an impurity diffusion region.

In FIG. 1, the N type impurity diffusion region used as the drain of first driver NMOS transistor N1 and the N type impurity diffusion region used as the drain of first access NMOS transistor N3 are shared by these transistors. Via contact part 4c formed on this N type impurity diffusion region, first metal wiring 5a, and contact parts (common contact) 4f, the drain of first driver NMOS transistor N1 and the drain of first access NMOS transistor N3 are connected with the drain of first load transistor P1. This terminal constitutes memory node Na of an equivalent circuit picture shown in FIG. 2.

Similarly the N type impurity diffusion region which is a drain of second driver NMOS transistor N2, and the N type impurity diffusion region which is a drain of second access NMOS transistor N3 connect with the drain of second load transistor P2 via contact part 4j, first metal wiring 5b, and contact parts (common contact) 4g. This terminal constitutes memory node Nb of an equivalent circuit picture shown in FIG. 2.

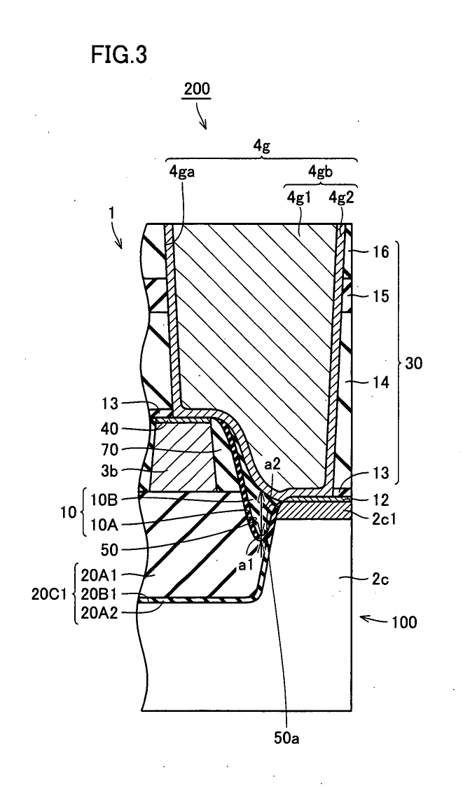

FIG. 3 is a cross-sectional view in the III-III line of FIG. 1, and is a cross-sectional view in contact parts 4g. As shown in this FIG. 3, on the main front surface of semiconductor substrate 100, isolation region 20c1 selectively formed on the main front surface of semiconductor substrate 100 and active region 2c specified by isolation region 20c1 on the main front surface of semiconductor substrate 100 are formed.

Isolation region 20c1 is provided with trench 20B1 formed on the main front surface of semiconductor substrate 1, insulating film 20A2 which is formed on the internal surface of this trench 20B1, and consists of a silicon oxide film etc., and insulating film 20A1 which were formed on this insulating film 20A2 and with which it filled up in trench 20B. Insulating film 20A1 comprises a silicon oxide film etc., for example. And on isolation insulating film 20A1, polysilicon wiring (wiring layer) 3b is formed. On the both side surfaces of this polysilicon wiring 3b, sidewall (side wall oxide film) 70 which consists of a silicon oxide film etc. is formed, for example.

Recess 50 which reaches active region 2c from sidewall 70 is formed in isolation insulating film 20A1. For this reason, the internal surface of recess 50 includes a part of front surface of impurity diffused layer 2c1, a part of front surface of active region 2c located under impurity diffused layer 2c1, and a part of front surface of isolation insulating film 20A1. And insulating film 10A which consists of a silicon oxide film etc. is formed so that the front surface of this recess 50 may be covered. The thickness of insulating film 10A of the vertical direction to the main front surface of semiconductor substrate 100 is about 20 nm in the parallel portion to the main front surface of semiconductor substrate 100. This insulating film 10A is formed on the side surface of sidewall 70 while it covers the internal surface of recess 50. On this insulating film 10A, insulating film 10B from which material differs in insulating film 10A, for example, the insulating film which consists of a silicon nitride film etc., is formed.

It fills up with this insulating film 10B in recess 50, and fills up with insulating film 10B to opening edge 50a of recess 50. And insulating film 10B is extending and existing even on the side surface of sidewall 70 via insulating film 10A. The thickness of this insulating film 10B of the vertical direction to the main front surface of semiconductor substrate 100 is formed more thickly than the thickness of insulating film 10A, for example, is about 80 nm. This insulating film 10B is an insulating film which consists of different material from insulating film 10A, for example, consists of a silicon nitride film etc. The insulating film which differs in material from insulating film 10A in this specification means that, when etching insulating film 10A, the etch rate difference of insulating film 10A including a silicon oxide film and insulating film 10B is larger than the etch rate difference of semiconductor substrate 100 of a P type, and a silicon oxide film. Preferably, insulating film 10B is formed with material including a silicon nitride film (Si3N4).

Thus, the inside of recess 50 is embedded by lamination insulating film 10 which consists of a plurality of insulating films 10A and 10B with a big difference of an etch rate. The outer edge section at the side of active region 2c of lamination insulating film 10 is located near the opening edge 50a of recess 50, and it is formed so that the upper surface of active region 2c may hardly be covered. Here, at least one side of insulating films 10A and 10B is formed so that the front surface of impurity diffused layer 2c1 may be contacted among the internal surfaces of recess 50. For this reason, the front surface of impurity diffused layer 2c1 located in recess 50 is covered with lamination insulating film 10. In particular, in Embodiment 1, among the internal surfaces of recess 50, at least, insulating film 10A is crossed to opening edge 50a from the bottom of recess 50, and it is formed so that the internal surface of recess 50 may be contacted. For this reason, among the internal surfaces of recess 50, the front surface of impurity diffused layer 2c1, and active region 2c located under impurity diffused layer 2c1 contacts insulating film 10A, and is covered with insulating film 10A.

Impurity diffusion region 2c1 is formed in the front surface of active region 2c which adjoins recess 50. On the front surface of this impurity diffusion region 2c1, silicide films 12, such as a cobalt silicide (CoSi2) film, are formed, for example. On the main front surface located in the opposite side with polysilicon wiring 3b, polysilicon wiring 3c shown in FIG. 1 is formed to this silicide film 12 among on the main front surface of active region 2c. The sidewall is formed also on the side surface of this polysilicon wiring 3c. And the end portion at the side of recess 50 of silicide film 12 is prescribed by the periphery part of lamination insulating film 10.

Here, at least one side of insulating films 10A and 10B has covered the front surface of impurity diffused layer 2c1 located in recess 50. It is suppressed that silicide film 12 is formed in impurity diffused layer 2c1 and the front surface of active region 2c among the internal surfaces of recess 50.

Thus, since it is suppressed that silicide film 12 contacts the front surface of active region 2c located in recess 50, it is suppressed that leakage current arises from silicide film 12 to semiconductor substrate 100. Thus, since it is suppressed that the leakage current from silicide film 12 to semiconductor substrate 100 occurs, reduction of consumed electric power can be aimed at and suppression of a generation of malfunction can be aimed at further.

Also on the upper surface of polysilicon wiring 3b, silicide film 40 which consists of a cobalt silicide film etc. is formed. And interlayer insulation film 30 is formed so that sidewall 70, polysilicon wiring 3b, and lamination insulating film 10 may be covered. This interlayer insulation film 30 is provided with insulating film 13 which is formed on silicide films 12 and 40 and consists of a plasma nitride (SiN) etc., insulating film 14 which is formed on insulating film 13 and consists of a HDP (high density plasma: High Density Plasma) film etc., insulating film 15 which is formed on this insulating film 14 and consists of a silicon oxide film formed by the CVD method using TEOS (Tetraethoxysilane) gas etc., and insulating film 16 formed on this insulating film 15.

Contact hole 4ga made an opening ranging from polysilicon wiring 3b upper part to impurity diffusion region 2c1 is formed in this interlayer insulation film 30. It fills up with electric conduction film 4gb in this contact hole 4ga. This electric conduction film 4gb is provided with electric conduction film 4g1, such as a barrier metal including TiN and Ti, and electric conduction film 4gb which was formed on this electric conduction film 4g1, and is filled up in contact hole 4ga and which was provided with electric conduction films 4g2, such as tungsten (W), for example. Electric conduction films 4g1 is formed on the internal surface of contact hole 4ga, and ranging from the upper surface of silicide film 40 to upper surface of silicide film 12. That is, contact parts 4g which connect between impurity diffusion regions 2c1 with polysilicon wiring 3b are formed in interlayer insulation film 30.

Here, the edge of lamination insulating film 10 located in the opening edge 50a side of recess 50 is located up from the bottom end of impurity diffusion region 2c1. For this reason, the portion at least located below from impurity diffusion region 2c1 among the side surfaces of active region 2c is covered with lamination insulating film 10 and isolation insulating film 20A2. Hereby, it is suppressed that contact parts 4g and the portion located below from impurity diffusion region 2c1 among active regions 2c are electrically connected. For this reason, it can suppress that the leakage current from contact parts 4g to semiconductor substrate 100 occurs. Reduction of consumed electric power can be aimed at in connection with this.

The front surface of insulating film 10B is made into a smooth curving surface over opening edge 50a of recess 50 from on the side surface of sidewall 70, and the end portion of insulating film 10B and silicide films 12 are formed successively gently-sloping. For this reason, the bottom of electric conduction film 4gb located on the boundary region of lamination insulating film 10 and active region 2c can be made into the shape of a flat surface. It can suppress that electric field concentration occurs and the generation of the leakage current to semiconductor substrate 100 can be suppressed further. In addition, although FIG. 3 explained the neighborhood of contact parts 4g, in contact parts 4f, it is formed similarly.

In FIG. 12, silicide film 40 is formed also on the upper surface of each gate wiring TG1 and TG2. On the upper surface of gate wiring TG2, the mask which consists of insulating films 10A and 10B remains, and silicide film 40 is formed on the upper surface of gate wiring TG2 which adjoins these insulating films 10A and 10B.

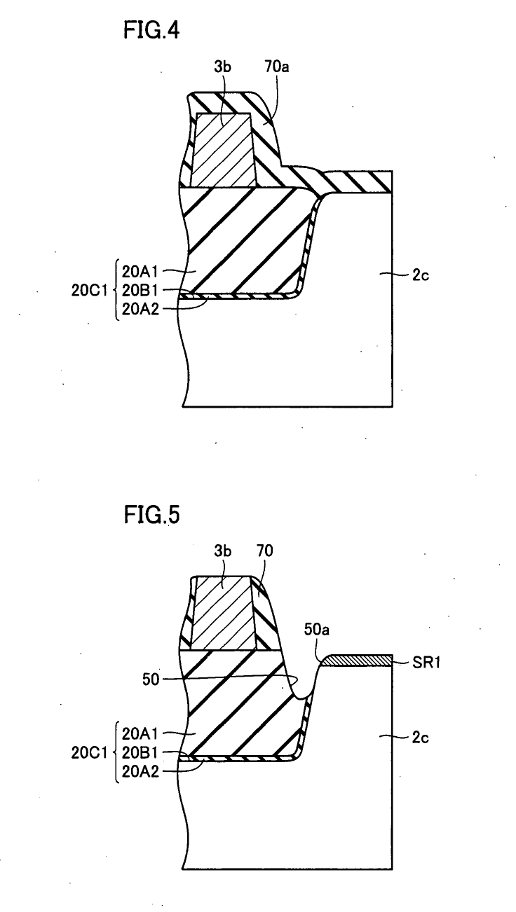

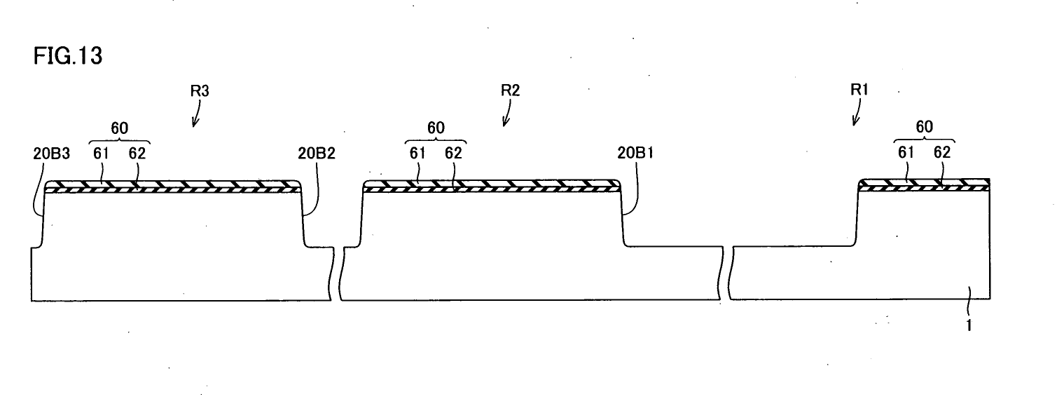

The manufacturing method of semiconductor device 200 concerning this embodiment is explained using FIG. 4-FIG. 11, and FIG. 13-FIG. 21.

FIG. 13 is a cross-sectional view showing the first step of the manufacturing process of semiconductor device 200. As shown in this FIG. 13, thermal oxidation is given to the main front surface of semiconductor substrate 100, and insulating film 62 is formed on the main front surface of semiconductor substrate 100. And insulating film 61 which consists of Si3N4 etc. is formed on the upper surface of this insulating film 62, for example, and mask layer 60 which consists of insulating film 61 and insulating film 62 is formed on the main front surface of semiconductor substrate 100.

A photolithography etc. is given to this mask layer 60 and the pattern according to the pattern of isolation region 20c1, 20c2, and 20c3 to form is formed in mask layer 60. And using mask layer 60 to which this patterning was given, it etches into the main front surface of semiconductor substrate 100, and trench 20B1, 20B2, and 20B3 are formed.

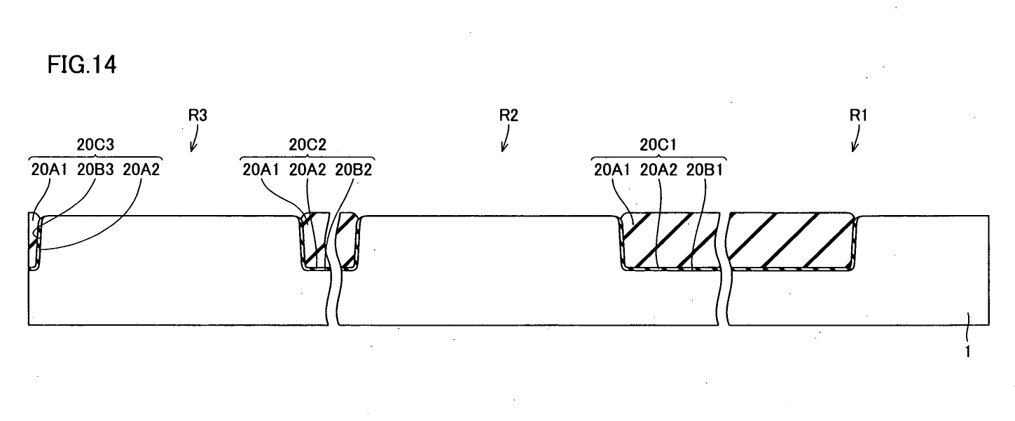

FIG. 14 is a cross-sectional view showing the second step of the manufacturing process of semiconductor device 200. As shown in this FIG. 14, it heat-treats to semiconductor substrate 100, and the insulating film which consists of a silicon oxide film etc. is formed on the internal surface of trench 20B1, 20B2, and 20B3.

And the insulating film which consists of a silicon oxide film etc. is deposited by the CVD method (Chemical Vapor Deposition) method using TEOS (Tetraethoxysilane) gas etc. Then, CMP etc. is given to this deposited insulating film and it is filled up with insulating film 20A1, respectively in trench 20B1, 20B2, and 20B3. And insulating film 61 is polished and removed, and it etches into insulating film 62 and removes.

Thus, on the main front surface of semiconductor substrate 100, isolation region 20c1, 20c2, and 20c3 are formed, and memory cell region R1, and the first, second peripheral circuit area R2 and R3 are specified.

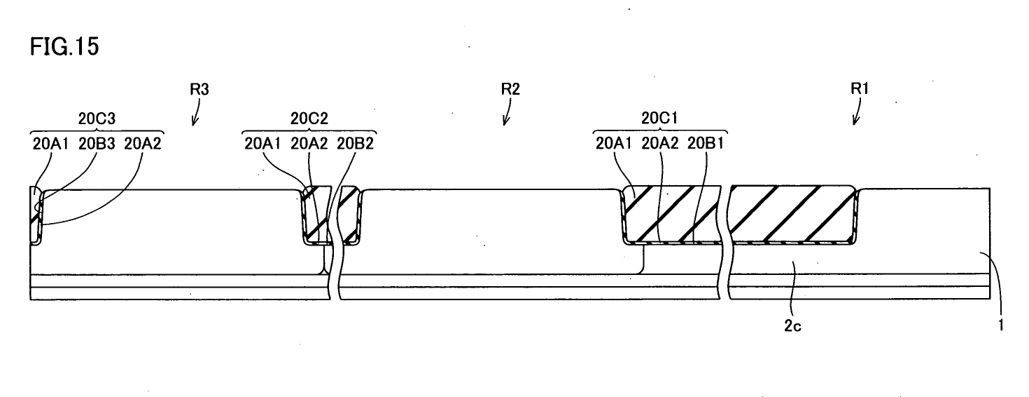

FIG. 15 is a cross-sectional view showing the third step of the manufacturing process of semiconductor device 200. In this FIG. 15, a resist layer is formed on the main front surface of semiconductor substrate 100, and a photolithography is given to this resist layer. And an impurity is selectively introduced (implanted) into the main front surface of semiconductor substrate 100, and the well region of various conductivity types is formed in the main front surface of semiconductor substrate 100 in which memory cell region R1, and the first, second peripheral circuit area R2 and R3 are located.

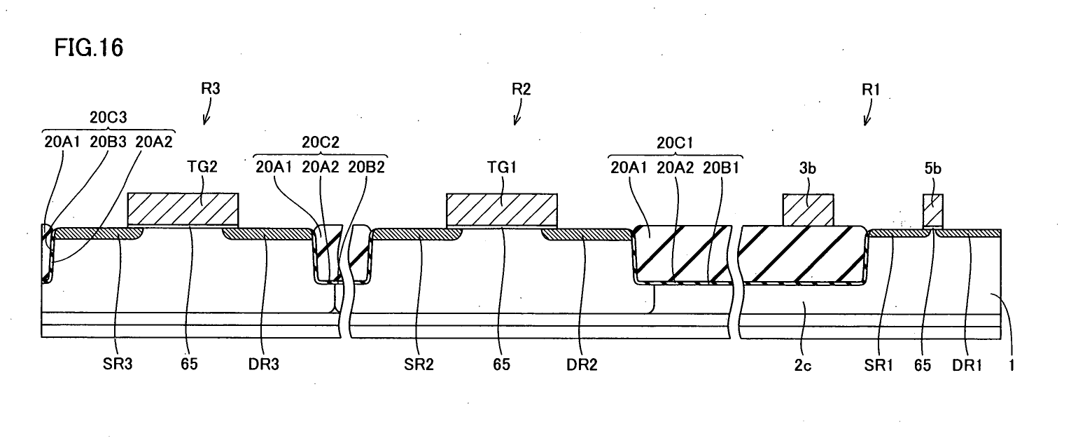

FIG. 16 is a cross-sectional view showing the fourth step of the manufacturing process of semiconductor device 200. As shown in this FIG. 16, it heat-treats to the main front surface of semiconductor substrate 100, and a silicon oxide film is formed on the main front surface of semiconductor substrate 100.

And on the main front surface of semiconductor substrate 100, a polysilicon film etc. is deposited and an impurity is introduced into this polysilicon film, for example. It patterns by using a photolithography etc. for the polysilicon film with which this impurity was introduced, and polysilicon wirings 5b and 3b, and gate wiring TG1 and TG2 are formed.

Using these formed polysilicon wirings 5b, and gate wiring TG1 and TG2 as a mask, an impurity is introduced into the main front surface of semiconductor substrate 100, and low-concentration impurity diffused layer SR1, DR1, DR2, SR2, DR3, and SR3 are formed.

FIG. 4 is a cross-sectional view showing the fifth step of the manufacturing process of semiconductor device 200. As shown in this FIG. 4, insulating film 70a which consists of a silicon oxide film etc. is deposited.

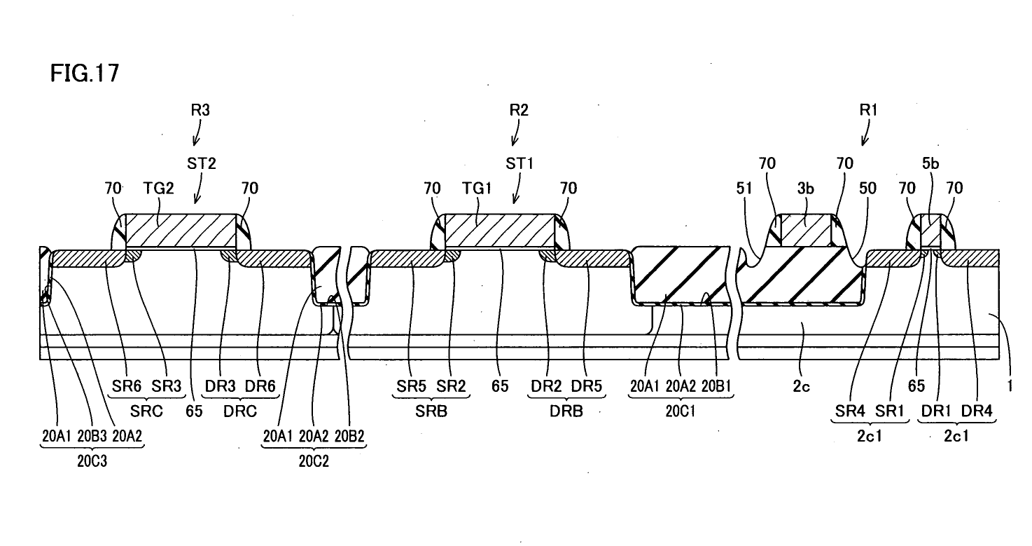

FIG. 5 and FIG. 17 are the cross-sectional views showing the sixth step of the manufacturing process of semiconductor device 200. As shown in this FIG. 5 and FIG. 17, it etches into insulating film 70a, and sidewall 70 is formed on the both side surfaces of gate wiring TG1, gate wiring TG2, polysilicon wiring 5b, and polysilicon wiring 3b.

On this occasion, the front surface at the side of impurity diffused layer SR1 among the front surfaces of isolation insulating film 20A1 is exposed from sidewall 70 formed on the side surface at the side of impurity diffused layer SR1 of polysilicon wiring 3b. Here, since isolation insulating film 20A1 and insulating film 20B1, and sidewall 70 comprise a homogeneous silicon oxide film etc., recess 50 is formed in the portion located in impurity diffused layer SR1 side from sidewall 70 among the front surfaces of isolation insulating film 20A1.

The front surface of isolation insulating film 20A1 which adjoins sidewall 70 formed on the side surface in which the side surface at the side of impurity diffused layer SR1 is opposed among the side surfaces of polysilicon wiring 3b is also exposed in this case. Recess 51 is formed also in the front surface of this isolation insulating film 20A1.

In FIG. 5, recess 50 formed in the front surface of isolation insulating film 20A1 is formed among isolation insulating films 20A1 ranging from sidewall 70 formed on the side surface at the side of impurity diffused layer SR1 of polysilicon wiring 3b to impurity diffused layer SR1.

And a part of front surface of impurity diffused layer SR1 and a part of front surface of active region 2c which are located under impurity diffused layer SR1 are exposed to the internal surface of recess 50.

Then, as shown in FIG. 17, an impurity is introduced into the main front surface of semiconductor substrate 100 which adjoins polysilicon wiring 5b, and impurity diffused layer SR4 and DR4 are formed in it. Hereby, impurity diffused layer 2c1 which consists of impurity diffused layer SR1 and impurity diffused layer SR4 is formed in the main front surface of semiconductor substrate 100 located in one side surface side of polysilicon wiring 5b. On the main front surface of semiconductor substrate 100 located in the other side surface side of polysilicon wiring 5b, impurity diffused layer 2c1 which consists of impurity diffused layer DR1 and impurity diffused layer DR4 is formed.

Impurity diffused layer DR5 and SR5 are similarly formed in the main front surface of semiconductor substrate 100 which adjoins gate wiring TG1. Hereby, impurity diffused layer DRB which consists of impurity diffused layer DR2 and impurity diffused layer DR5 is formed in the main front surface of semiconductor substrate 100 located in one side surface side of gate wiring TG1. And impurity diffused layer SRB which consists of impurity diffused layer SR5 and impurity diffused layer SR2 is formed in the main front surface of semiconductor substrate 100 located in the other side surface side.

An impurity is introduced into the main front surface of semiconductor substrate 100 which adjoins gate wiring TG2, and impurity diffused layer DR6 and impurity diffused layer SR6 are formed in it. Hereby, impurity diffused layer DRC which consists of impurity diffused layer DR3 and impurity diffused layer DR6 is formed in the main front surface of semiconductor substrate 100 located in one side surface side of gate wiring TG2. Impurity diffused layer SRC which consists of impurity diffused layer SR3 and impurity diffused layer SR6 is formed in the main front surface of semiconductor substrate 100 located in the other side surface side of gate wiring TG2.

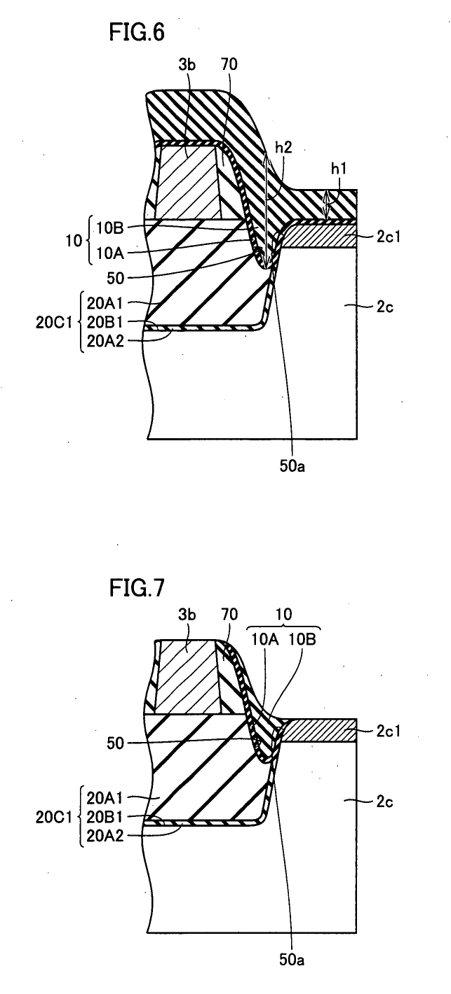

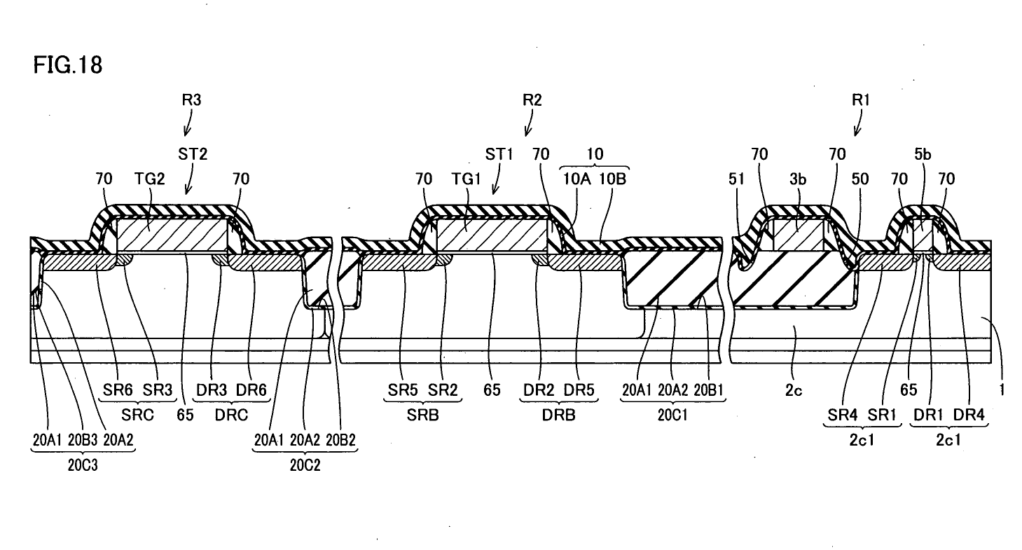

FIG. 6 and FIG. 18 are the cross-sectional views showing the seventh step of the manufacturing process of semiconductor device 200. As shown in this FIG. 6 and FIG. 18, it is a region including recess 50 and insulating film 10A which consists of a silicon oxide film etc. is formed as a silicide protection film on the main front surface of semiconductor substrate 100, for example. For example, about 20 nm-30 nm of insulating films 10A are deposited by the CVD method (Chemical Vapor Deposition) method using TEOS (Tetraethoxysilane) gas. Since the depth of recess 50 is set to about 60 nm in many cases, for example, insulating film 10A is formed so that it may go along on the front surface of recess 50.

And after forming insulating film 10A, about 80 nm-100 nm of insulating films 10B which consist of a silicon nitride film etc. are formed with a CVD method etc. on insulating film 10A, for example. Thus, insulating film 10B is deposited so that the thickness of deposited insulating film 10B may become thick rather than the depth of recess 50.

Here, thickness h2 of a vertical direction to the main front surface of semiconductor substrate 100 of the portion located on recess 50 among insulating films 10B is for example, formed thicker than thickness h1 of the portion located on impurity diffusion region 2c1 among insulating films 10B, and thicker than insulating film 10B further formed on polysilicon wiring 3b.

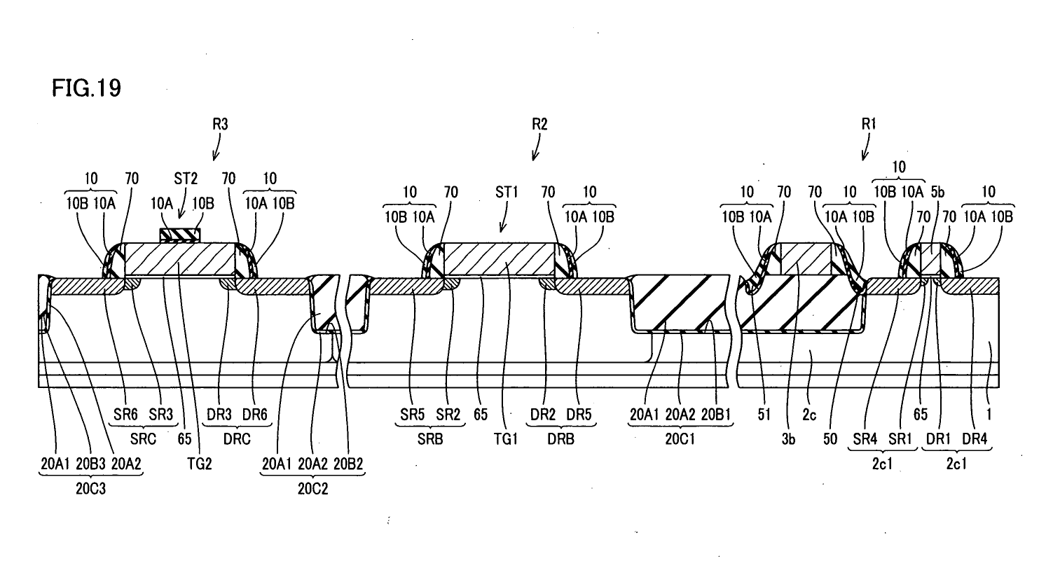

FIG. 7 and FIG. 19 are the cross-sectional views showing the eighth step of the manufacturing process of semiconductor device 200. In this FIG. 7 and FIG. 19, it patterns to a silicide protection film first. It etches into insulating film 10B by using insulating film 10A as a stopper. Here, insulating film 10A consists of a silicon oxide film etc., and insulating film 10B consists of a silicon nitride film etc. For this reason, when etching insulating film 10B, the large selection ratio of etching is taken so that the side of a silicon nitride film may become easier to etch than a silicon oxide film. For this reason, insulating film 10A can be operated good as a stopper. When etching into insulating film 10B, it can suppress etching to the main front surface of semiconductor substrate 100.

In this embodiment, as a combination of insulating film 10A and insulating film 10B, as mentioned above, insulating film 10A was made into the silicon oxide film, and insulating film 10B was made into the silicon nitride film. Besides it, for example, insulating film 10A is made into a silicon oxide film, and it is good also considering insulating film 10B as a silicon oxynitride (SiON) film. In order to form insulating film 10B which consists of a silicon oxynitride film, a silicon oxide film is formed on insulating film 10B, and it forms by annealing in NO and N2O atmosphere, for example.

As a combination of insulating film 10A and insulating film 10B, insulating film 10A is made into a silicon oxide film, and it is good also considering insulating film 10B as a SOG (liquid glass: spin on glass) film. Thus, by adopting a SOG film as insulating film 10B, SOG liquid enters easily in recess 50, and it can suppress that a seam etc. is formed.

As a combination of insulating film 10A and insulating film 10B, insulating film 10A is made into a silicon oxide film, and it is good also considering insulating film 10B as a plasma nitride (SiN) film. Form degradation of sidewall 70 can be suppressed by using a plasma nitride film as insulating film 10B. As insulating film 10A, a silicon oxide film is formed with the CVD method using TEOS (Tetraethoxysilane) gas etc., and it is good also considering insulating film 10B as a HDP (high density plasma: High Density Plasma) film.

Thus, all of insulating films 10A and 10B can distinguish between the etch rate of formed insulating films 10A and 10B with each manufacturing method. Insulating film 10A can be operated as a stopper at the time of etching insulating film 10B.

And when insulating film 10A formed on the upper surface of impurity diffusion region 2c1 and the upper surface of polysilicon wiring 3b is exposed, etching of insulating film 10B is stopped. Here, the thickness of insulating film 10B formed on recess 50 and sidewall 70 is formed more thickly than insulating film 10B formed on impurity diffusion region 2c1 and polysilicon wiring 3b. For this reason, when upper surface of polysilicon wiring 3b and upper surface of impurity diffusion region 2c1 is exposed, the inside of recess 50 will be in the state where insulating film 10B was filled up. It will be in the state where insulating film 10B remained also on sidewall 70.

Thus, after etching into insulating film 10B, it etches into insulating film 10A, and upper surface of impurity diffusion region 2c1 and upper surface of polysilicon wiring 3b is exposed. Here, since the thickness of insulating film 10A is formed in about 20 nm filmy, the upper surface of impurity diffusion region 2c1 and the upper surface of polysilicon wiring 3b can be exposed by performing light etching to insulating film 10A. For this reason, it can suppress that an etching damage is given to the upper surface of impurity diffusion region 2c1, and the upper surface of polysilicon wiring 3b. Thus, in recesses 50 and 51, insulating film 10A formed along the internal surface of recesses 50 and 51 and insulating film 10B which is formed on the upper surface of this insulating film 10A, and fills up the inside of recesses 50 and 51 are formed.

In FIG. 7, by etching into insulating film 10A, lamination insulating film 10 which consists of insulating film 10A and insulating film 10B is formed over the upper surface of sidewall 70 from the boundary region of the upper surface and the side surface of active region 2c, and it fills up with it in recess 50. And the edges of lamination insulating film 10 are smoothly formed successively to the upper surface of exposed impurity diffusion region 2c1. The upper surface of lamination insulating film 10 is made into the smooth curving surface ranging from the upper surface side of impurity diffusion region 2c1 to the sidewall 70 side. Here, a part of front surface of impurity diffused layer 2c1 exposed in recess 50 and a part of front surface of active region 2c which are located under impurity diffused layer 2c1 touch either insulating film 10A or insulating film 10B at least.

A part of insulating films 10A and 10B are made to remain on the upper surface of gate wiring TG2 in this embodiment.

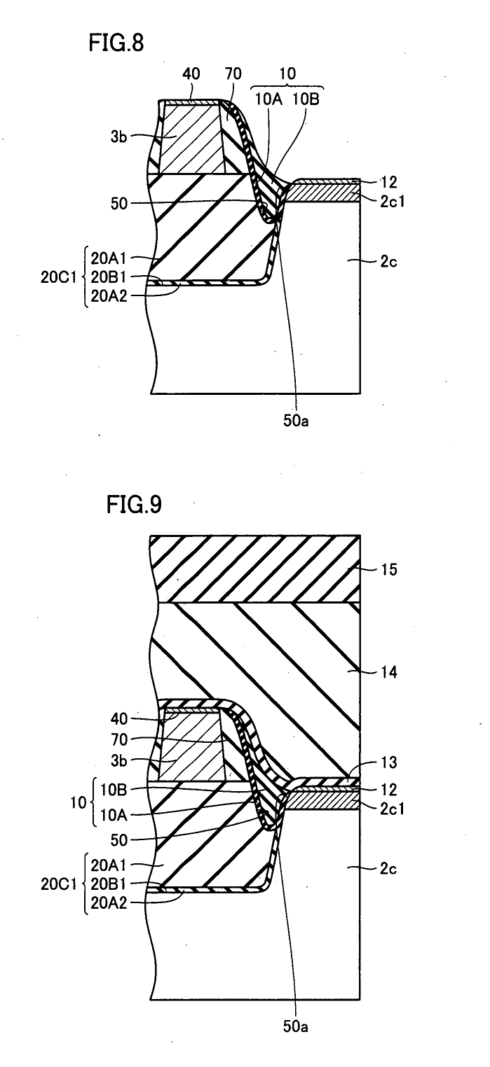

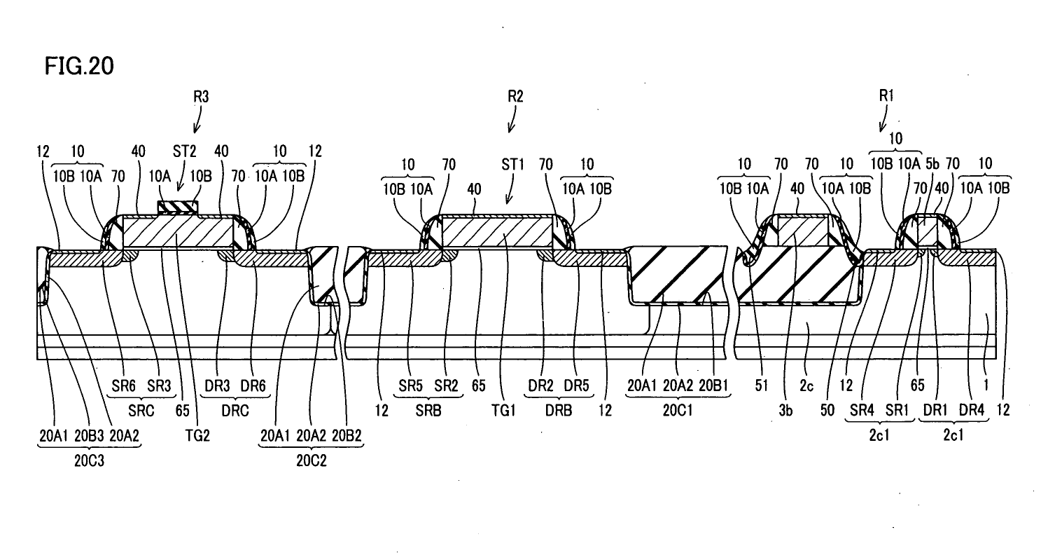

FIG. 8 and FIG. 20 are the cross-sectional views showing the ninth step of the manufacturing process of semiconductor device 200. Since it fills up with lamination insulating film 10 in recess 50, it can suppress that the internal surface of recess 50 is exposed. And metallic films, such as cobalt (Co), are deposited, about 10 nm, on the main front surface of semiconductor substrate 100 by the sputtering method.

Then, heat treatment about more than 400° C. and below 600° C. is performed, silicon and cobalt react (silicidation), and silicide films 12 and 40 are formed. And wet etching removes unreacted cobalt. After an appropriate time, it heat-treats in the range of more than 700° C. and less than 800° C. Thus, silicide film 12 is formed on the front surface of impurity diffused layer 2c1, 2c1, SRB, DRB, SRC, and DRC. Silicide film 40 is formed on the upper surface of polysilicon wiring 5b and 3b and gate wiring TG1. Since insulating films 10A and 10B remain on the upper surface of gate wiring TG2, silicide film 40 is formed on the upper surface of gate wiring TG2 which adjoins insulating films 10A and 10B.

Thus, when forming silicide films 12 and 40, the front surface of impurity diffused layer 2c1 exposed in recess 50 and the front surface of active region 2 located under impurity diffused layer 2c1 touch lamination insulating film 10 which consists of insulating film 10A and insulating film 10B. For this reason, it is suppressed that a silicide film is formed in the front surface of impurity diffused layer 2c1 located in recess 50 and the front surface of active region 2c located under impurity diffused layer 2c1.

That is, it is suppressed that silicide film 12 formed on the upper surface of impurity diffused layer 2c1 reaches even the front surface of active region 2c which is located under impurity diffused layer 2c1 extending and existing even over the internal surface of recess 50. For this reason, it can suppress that silicide film 12 formed and semiconductor substrate 100 are electrically connected.

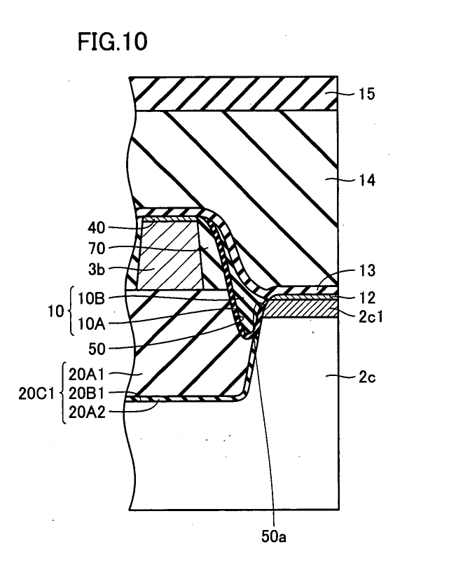

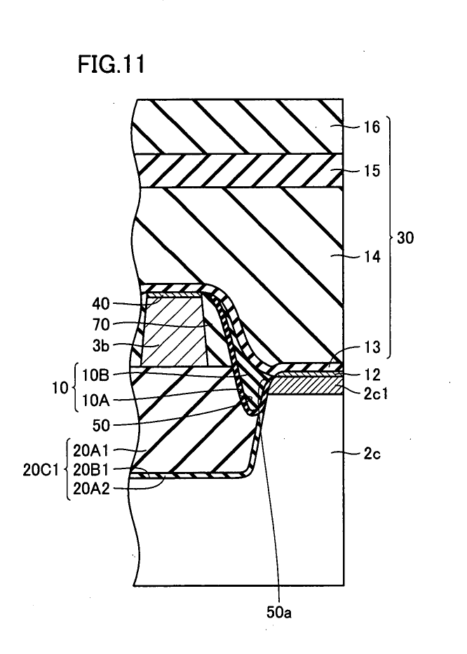

FIG. 9 is a cross-sectional view showing the 10th step of the manufacturing process of semiconductor device 200, FIG. 10 is a cross-sectional view showing the 11th step, and FIG. 11 and FIG. 21 are the cross-sectional views showing the 12th step. And as shown in FIG. 11 from FIG. 9, insulating film 13 which consists of a plasma nitride (P-SiN) film etc. is formed on polysilicon wiring 3b, sidewall 70, and the main front surface of semiconductor substrate 100 formed on impurity diffusion region 2c1 first.

And insulating film 14 which consists of a HDP (high density plasma: High Density Plasma) film etc. is formed on this insulating film 13. On this insulating film 14, insulating film 15 is formed with the CVD method which used for example, TEOS (Tetraethoxysilane) gas. Insulating film 16 is formed on the upper surface of insulating film 15, and interlayer insulation film 30 is formed.

And as shown in FIG. 3, contact hole 4ga is formed in interlayer insulation film 30. Thus, after forming interlayer insulation film 30, contact hole 4ga formed in interlayer insulation film 30 ranging from on the upper surface of silicide film 12 to silicide film 40 is formed.

Then, electric conduction film 4g1, such as a barrier metal, is formed on the internal surface of this contact hole 4ga, and electric conduction films 4g2, such as tungsten, are formed on this electric conduction film 4g1. Thus, the contact parts 4g which electrically connect impurity diffusion region 2c1 and polysilicon wiring 3b are formed via silicide films 12 and 40 on the main front surface of semiconductor substrate 100.

In FIG. 1, other polysilicon wirings 3a, 3c, and 3d are formed similarly, and contact parts 4f are formed like contact parts 4g.

In this embodiment, although lamination insulating film 10 comprises insulating film 10A and insulating film 10B, it is not restricted to this. For example, lamination insulating film 10 may consist of only insulating films 10A, making the thickness of a vertical direction to the main front surface of semiconductor substrate 100 of insulating film 10A about 80 nm. The step which manufactures semiconductor device 200 has a step which cleans the region in which memory cell 1 was formed.

Here, it can suppress that recess 50 becomes still larger according to a cleaning process by forming insulating film 10 in the front surface of recess 50 as mentioned above. In this embodiment, although the case where the present invention was applied to full CMOSSRAM was explained, it is not restricted to this full CMOSSRAM. For example, the present invention is applicable to a content addressable memory (CAM) etc. The embodiment of the invention was explained as mentioned above. It should be thought that the embodiment disclosed this time is exemplification at all points, and not restrictive. The range of the present invention is shown by the claim. It is meant that equivalent meaning, and all the change within the limits as a claim are included.

The present invention is suitable for a semiconductor device and its manufacturing method.

What is claimed is:

1. A semiconductor device, comprising:
a semiconductor substrate which has a main front surface;
an isolation insulating film selectively formed over a main front surface of the semiconductor substrate;
an active region specified by the isolation insulating film over a main front surface of the semiconductor substrate;
a recess which reaches the active region over the isolation insulating film;
a first insulating film formed in the recess;
a second insulating film which is formed over the first insulating film, fills up the recess, and differs in material from the first insulating film;
an impurity diffused layer formed in a front surface of the active region of a position which adjoins the recess; and
a conductive layer which is formed over the impurity diffused layer and is electrically connected with the impurity diffused layer.

2. A semiconductor device according to claim 1, wherein
a thickness of the second insulating film of a vertical direction to a main front surface of the semiconductor substrate is thicker than a thickness of the first insulating film of a vertical direction to a main front surface of the semiconductor substrate.

3. A semiconductor device according to claim 1, further comprising:
a silicide film formed over the impurity diffused layer.

4. A semiconductor device according to claim 1, further comprising:
a wiring layer formed over the isolation insulating film;
a side wall insulating film formed over a side wall of the wiring layer; and
an interlayer insulation film which has a contact hole ranging from over the wiring layer to the impurity diffused layer upper part;
wherein
the conductive layer is formed in the contact hole.

5. A semiconductor device, comprising:
a semiconductor substrate which has a main front surface;
an isolation insulating film selectively formed over a main front surface of the semiconductor substrate;
an active region specified by the isolation insulating film over a main front surface of the semiconductor substrate;
a first impurity diffused layer which was formed in a front surface of the active region which adjoins the isolation insulating film, and whose front surface was silicided;
a second impurity diffused layer which is formed in a front surface of the active region making a gap with the first impurity diffused layer, and whose front surface is not silicided;
a recess which reaches the first impurity diffused layer over the isolation insulating film;
a first insulating film formed in the recess; and
a second insulating film which is formed over the first insulating film, fills up the recess, and differs in material from the first insulating film;
wherein
at least, either the first insulating film or the second insulating film reaches the first impurity region.

6. A semiconductor device according to claim 5, further comprising:
an interlayer insulation film which has a contact hole ranging from over the wiring layer to the first impurity diffused layer upper part; and
an electric conduction film formed in the contact hole.

7. A method of manufacturing a semiconductor device, comprising the steps of:
forming an isolation insulating film which specifies an active region over a main front surface of a semiconductor substrate;
introducing an impurity into a front surface of the active region which adjoins the isolation region, and forming an impurity diffused layer;
forming a first insulating film so that the impurity diffused layer and the isolation insulating film may be covered;
selectively etching the first insulating film, and exposing a front surface of the isolation insulating film at a side of the impurity diffused layer;
forming a second insulating film in a recess formed by etching of the first insulating film so that it might reach the active region in the isolation insulating film front surface;
filling up the recess with a third insulating film while forming the third insulating film whose material differs from the second insulating film over the second insulating film; and
forming an electric conduction film electrically connected with this impurity diffused layer over the impurity diffused layer.

8. A method of manufacturing a semiconductor device according to claim 7, further comprising a step of:
forming a silicide film over the impurity diffused layer after filling up the recess with the third insulating film.

9. A method of manufacturing a semiconductor device, comprising the steps of:
forming an isolation insulating film which specifies an active region over a main front surface of a semiconductor substrate;
introducing an impurity into a front surface of the active region selectively, and forming a first impurity diffused layer in a front surface of the active region of a position which adjoins the isolation insulating film;
introducing an impurity into a front surface of the active region selectively, and forming a second impurity region in a front surface of the active region making a gap with the first impurity region;
forming a first insulating film so that the second impurity region and the isolation insulating film may be covered;
etching the first insulating film selectively, and exposing a front surface of the isolation insulating film at a side of the first impurity diffused layer;
forming a second insulating film in a recess formed so that it might reach the active region in a front surface of the isolation insulating film by etching of the first insulating film;
filling up an inside of the recess with a third insulating film while forming the third insulating film whose material differs from the second insulating film over the second insulating film;
forming a mask layer which covers the third insulating film, and exposes the first impurity diffused layer; and
siliciding an exposed front surface of the first impurity diffused layer.
